(19) United States
(12) Patent Application Publication
(10) Pub. No.: US 2017/0338293 A1
(43) Pub. Date: Nov. 23, 2017

(54) Array Substrate and Method for Fabricating the Same, and Display Apparatus

(71) Applicant: BOE TECHNOLOGY GROUP CO., LTD., Beijing (CN)

(72) Inventor: Yidong GUO, Beijing (CN)

(73) Assignee: BOE TECHNOLOGY GROUP CO., LTD., Beijing (CN)

(21) Appl. No.: 15/533,813

(22) PCT Filed: Oct. 13, 2016
(86) PCT No.: PCT/CN2016/102006

§ 371 Date: Jun. 7, 2017

(30) Foreign Application Priority Data
Nov. 13, 2015 (CN) 201510781025.4

(51) Int. Cl. H01L 27/32

(52) U.S. Cl. CPC H01L 27/3267; H01L 27/3288; H01L 27/3276; H01L 27/3286; H01L 2227/323

(57) ABSTRACT

The present disclosure provides an array substrate, a method for fabricating the same and a display apparatus, which belongs to the field of display technology and may alleviate at least a problem of wide bezel of a display apparatus in the related art. The array substrate includes a display region and a periphery region abutting the display region, the display region being provided with a plurality of AM-OLEDs therein. The array substrate further includes a plurality of PM-OLEDs provided in the periphery region, wherein both of the plurality of AM-OLEDs and the plurality of PM-OLEDs are electrically connected to a power supply driving unit. Since the plurality of PM-OLEDs capable of emitting light are disposed in the periphery region, the array substrate according to the present disclosure can realize a narrow-bezel design.

### FIELD

The present invention belongs to the field of display technology, and specifically relates to an array substrate, a method for fabricating the same, and a display apparatus.

### BACKGROUND

As a novel flat-panel display, an organic light-emitting diode (OLED) device has been increasingly concerned due to its characteristics such as active light-emission, high brightness, wide view angle, fast response, low power consumption and flexibleness, and has become next generation of display technology which is likely to take over liquid crystal display. OLEDs are classified into active-matrix OLEDs (AM-OLEDs) and passive-matrix OLEDs (PM-OLEDs) by driving mode.

A typical structure of PM-OLED consists of a glass substrate, an ITO (indium tin oxide) anode, an organic light emitting layer, a cathode and the like, and has the characteristics of simple structure, less driving lines, less occupied area of a peripheral circuit and so on.

AM-OLED is adopted in each sub-pixel of a display panel. Each sub-pixel is further provided with a low temperature poly-silicon thin film transistor (LTP-Si TFT) having a switch function and a charge storage capacitor therein, and a peripheral circuit and a display array are integrated as a whole system on a same glass substrate. AM-OLED has the advantages of fast response, high contrast ratio, wide color gamut, energy saving and so on, and becomes the mainstream of OLED technology. However, since each LTP-Si TFT is provided with numerous peripheral lines such as a gate driving line, source and drain driving lines and the like and light cannot be emitted from an area occupied by these lines, a display apparatus inevitably has a black area of a certain width in which image cannot be displayed, namely, a bezel region of the display panel, resulting in that a narrow bezel of the display panel cannot be achieved.

### SUMMARY

In view of the above problems in the existing array substrates, the present disclosure provides an array substrate, a method for fabricating the same and a display apparatus which can realize a narrow-bezel design.

In one aspect, the present disclosure provides an array substrate, which includes a display region and a periphery region being on a periphery of the display region, the display region being provided with a plurality of AM-OLEDs therein. The array substrate further includes a plurality of PM-OLEDs provided in the periphery region, wherein both of the plurality of AM-OLEDs and the plurality of PM-OLEDs are electrically connected to a power supply driving unit.

Optionally, top electrodes of the AM-OLEDs and top electrodes the PM-OLEDs are disposed in a same layer and made of a same material;

bottom electrodes of the AM-OLEDs and bottom electrodes the PM-OLEDs are disposed in a same layer and made of a same material; and

a light emitting layer of the AM-OLEDs and a light emitting layer the PM-OLEDs are disposed in a same layer and made of a same material.

Optionally, the plurality of PM-OLEDs are arranged in a matrix, the bottom electrodes of the PM-OLEDs in a same row are connected to each other to form an integral structure, and the top electrodes of the PM-OLEDs in a same column are connected to each other to form an integral structure.

Optionally, the array substrate further includes a gate driving circuit disposed, in the periphery region, under a layer at which the PM-OLEDs are positioned, the gate driving circuit being configured to drive the plurality of AM-OLEDs.

Optionally, the array substrate further includes a plurality of switch transistors disposed, in the display region, under a layer at which the AM-OLEDs are positioned, wherein a drain electrode of each of the plurality of switch transistors is connected to a bottom electrode of a corresponding one of the plurality of AM-OLEDs.

Optionally, the array substrate further includes a plurality of first spacers disposed on a pixel defining layer of the AM-OLEDs in the display region, and a plurality of second spacers disposed on a pixel defining layer of the PM-OLEDs in the periphery region.

Optionally, each of the first spacers has a shape of trapezoid, and each of the second spacers has a shape of inverted trapezoid.

Optionally, the top electrodes of the AM-OLEDs are formed integrally.

Optionally, the array substrate further includes a non-display region located on an outermost periphery of the array substrate, the non-display region corresponding to a bezel of the array substrate.

In another aspect, the present disclosure provides a method for fabricating an array substrate, the array substrate including a display region and a periphery region abutting the display region, and the method includes: forming a plurality of AM-OLEDs on a substrate in the display region; and

forming a plurality of PM-OLEDs on the substrate in the periphery region,

wherein both of the plurality of AM-OLEDs and the plurality of PM-OLEDs are electrically connected to a power supply driving unit.

Optionally, top electrodes of the AM-OLEDs and top electrodes of the PM-OLEDs are formed by one patterning process;

bottom electrodes of the AM-OLEDs and bottom electrodes of the PM-OLEDs are formed by one patterning process; and

a light emitting layer of the AM-OLEDs and a light emitting layer of the PM-OLEDs are formed by one patterning process.

Optionally, before forming the top electrodes of the AM-OLEDs and the top electrodes of the PM-OLEDs by one patterning process, the method further includes:

forming a plurality of first spacers on a pixel defining layer of the AM-OLEDs in the display region; and forming a plurality of second spacers on a pixel defining layer of the PM-OLEDs in the periphery region.

Optionally, each of the first spacers is formed to have a shape of trapezoid, and each of the second spacers is formed to have a shape of inverted trapezoid.

Optionally, the plurality of PM-OLEDs are formed to be arranged in a matrix, bottom electrodes of the PM-OLEDs in a same row are formed integrally, and top electrodes of the PM-OLEDs in a same column are formed integrally.

Optionally, before forming the plurality of PM-OLEDs in the periphery region, the method further includes:

forming a gate driving circuit on the substrate in the periphery region.

Optionally, before forming the plurality of AM-OLEDs in the display region, the method further includes:

forming switch transistors on the substrate in the display region,

wherein the switch transistors on the substrate in the display region and the gate driving circuit on the substrate in the periphery region are formed by a same patterning process.

Optionally, before forming the plurality of AM-OLEDs in the display region, the method further includes:

forming a plurality of switch transistors on the substrate in the display region; and

forming a planarization layer on the plurality of switch transistors, and forming, on a drain electrode of each of the plurality of switch transistors, a via penetrating the planarization layer,

wherein the drain electrode of each of the plurality of switch transistors is connected to a bottom electrode of a corresponding one of the AM-OLEDs through the via.

In still another aspect, the present disclosure provides a display apparatus including any one of the above array substrates.

The beneficial effects of the present disclosure are as follows.

The periphery region of the array substrate according to the present disclosure is provided with the plurality of PM-OLEDs which enables light emission of the periphery region of the array substrate, and thus a display with narrow bezel design can be realized.

The method for fabricating an array substrate according to the present disclosure is simple and easy to operate.

The display apparatus according to the present disclosure has a narrow bezel due to the above array substrate included therein.

### BRIEF DESCRIPTION OF THE DRAWINGS

FIG. 1 is a schematic plan view of an array substrate according to an embodiment of the present invention;

FIG. 2 is a cross sectional diagram taken along line A-A′ in FIG. 1;

FIG. 3 is a schematic diagram illustrating step six of a method for fabricating an array substrate according to an embodiment of the present invention;

FIG. 4 is a schematic diagram illustrating step seven of the method for fabricating an array substrate according to an embodiment of the present invention;

FIG. 5 is a schematic diagram illustrating step eight of the method for fabricating an array substrate according to an embodiment of the present invention; and

FIG. 6 is a schematic diagram illustrating step nine of the method for fabricating an array substrate according to an embodiment of the present invention.

### DETAILED DESCRIPTION

To make those skilled in the art better understand the technical solutions of the present disclosure, the present disclosure will be further described in detail below in conjunction with the accompanying drawings and specific implementations.

First, it should be noted that, OLEDs include upright OLEDs and inverted OLEDs, wherein an upright OLED has a cathode disposed above its anode, namely, the cathode is a top electrode and the anode is a bottom electrode, and an inverted OLED has an anode disposed above its cathode, namely, the cathode is a bottom electrode and the anode is a top electrode. The following embodiments are described by taking the upright OLED for example, but it is not intended to limit the present invention, and the inverted OLED shall fall into the protective scope of the present invention.

In embodiments of the present invention, a patterning process may include only a photolithography process; alternatively, the patterning process may include not only the photolithography process and etching steps but also other processes for forming a predetermined pattern such as printing, ink jetting and the like, wherein the photolithography process refers to a process for forming a pattern by using a photoresist, a mask plate, an exposure machine and the like, including steps of film formation, exposure, development and so on. Specific patterning process may be selected according to the structure to be formed in embodiments of the present invention.

Hereinafter, an array substrate, a method for fabricating the same and a display apparatus according to the present disclosure will be described in conjunction with the following embodiments.

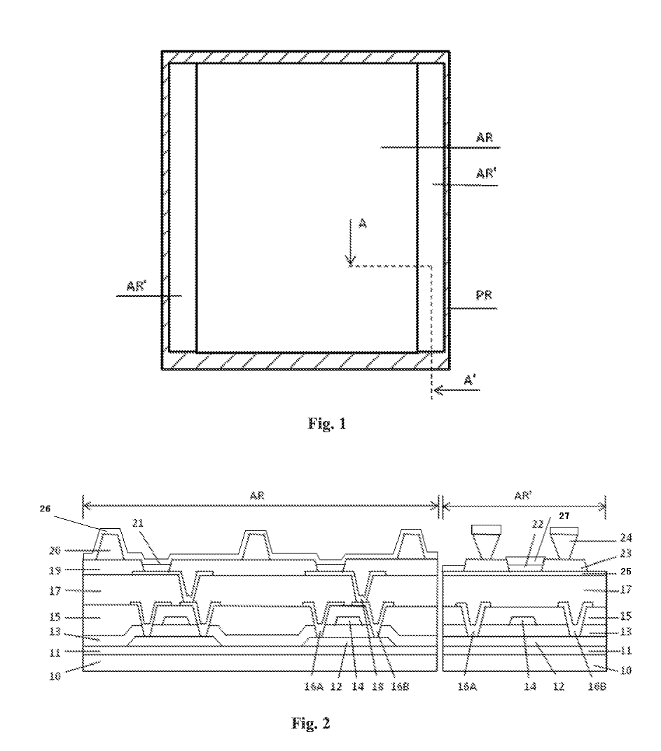

As illustrated in FIGS. 1 and 2, an embodiment of the present invention provides an array substrate, which includes a display region AR and a periphery region AR′ abutting the display region AR (‘PR’ in the drawings refers to the entire non-display region), the display region AR being provided with a plurality of AM-OLEDs therein and the periphery region AR′ being provided with a plurality of PM-OLEDs therein; wherein both of the plurality of AM-OLEDs and the plurality of PM-OLEDs are electrically connected to a power supply driving unit. it should be noted that, the periphery regions AR′ are disposed at both sides of the display region AR, but the present disclosure is not limited thereto. The periphery regions AR′ may also be disposed at all sides of the display region AR, and alternatively, at arbitrary one or more sides of the display region AR.

Those skilled in the art should be understood that, specifically, the array substrate includes a substrate 10, and a plurality of gate lines and a plurality of data lines (not shown in the drawings) disposed on the substrate 10, which intersect with and are insulated from each other; wherein each of the intersections of adjacent gate lines and adjacent gate lines defines one pixel, each of the pixels including a light emitting element and a switch transistor for driving the light emitting element. The light emitting element is implemented as a plurality of AM-OLEDs according to an embodiment of the present invention, each of which is controlled by a switch transistor connected thereto (a drain 16B of each switch transistor is connected to the anode 18 of a corresponding one of the AM-OLEDs) to emit light. A region of the array substrate in which the pixels are located is adapted to display an image, and is referred to as the display region AR. A region on the periphery of the display region AR is referred to as the periphery region AR′. In the related art, the display region is directly surrounded by a bezel region with no display function. However, in the embodiments of the present invention, there is provided a periphery region AR′ abutting one or more sides of the display region AR, and a plurality of PM-OLEDs are provided in the periphery region AR′, each of which has a cathode 27 and an anode 25 applied with respective voltages by the power supply driving unit without being controlled by the switch transistors. Due to the PM-OLEDs provided in the periphery region AR′, the periphery region AR′ of the array substrate is capable of emitting light, resulting in that a width of a non-display bezel is effectively decreased, a total area for displaying an image is enlarged, and a narrow-bezel design is achieved.

In an embodiment of the present invention, the anodes 18 of the AM-OLEDs and the anodes 25 of the PM-OLEDs are disposed in a same layer and made of a same material, namely, the anodes 18 and 25 may be formed by one patterning process. The cathodes 26 of the AM-OLEDs and the cathodes 27 of the PM-OLEDs are disposed in a same layer and made of a same material, namely, the cathodes 26 and 27 may be formed by one patterning process. A light emitting layer 21 of the AM-OLEDs and a light emitting layer 22 of the PM-OLEDs are disposed in a same layer and made of a same material, namely, the light emitting layers 21 and 22 may be formed by one patterning process. It can be seen that the number of patterning processes during fabrication of the array substrate according to an embodiment of the present invention does not increase, so the production efficiency can be improved and the production cost can be saved.

In an embodiment of the present invention, the plurality of PM-OLEDs disposed in the periphery region AR′ may be arranged in a matrix, wherein the anodes 25 of the PM-OLEDs in a same row are connected to each other to form an integral structure and the cathodes 27 of the PM-OLEDs in a same column are connected to each other to form an integral structure. In this way, for example, a first PM-OLED in a first row may be controlled to emit light when voltages are applied, by the power supply driving unit, to the anodes in the first row and the cathodes in a first column, respectively, and accordingly, such arrangement can not only not increase the number of processes, but also enable individual control of each PM-OLED.

In an embodiment of the present invention, the periphery region AR′ of the array substrate is further provided with a gate driving circuit under a layer at which the PM-OLEDs are positioned, which is a GOA circuit for driving the AM-OLEDs, thereby further decreasing the width of the bezel region of the array substrate.

The array substrate further includes a plurality of first spacers 20 disposed on an pixel defining layer of the AM-OLEDs in the display region AR, and a plurality of second spacers 24 disposed on a pixel defining layer of the PM-OLEDs in the periphery region AR′.

Optionally, the first spacer 20 has a shape of trapezoid; and the second spacer 24 has a shape of inverted trapezoid.

The first spacers 20 of trapezoid shape and the second spacers 24 of inverted trapezoid shape are provided for the following reasons. During the formation of the cathodes 26 of AM-OLEDs and the cathodes 27 of PM-OLEDs by one evaporation process, the cathodes of all AM-OLEDs are formed integrally, and due to the fact that the first spacers 20 of trapezoid shape have sides gently extending outwards, the cathodes 26 of the AM-OLEDs is unlikely to crack; whereas the cathodes 27 of the PM-OLEDs in a same row are separately arranged, so the second spaces 24 of inverted trapezoid shape facilitates formation of the plurality of disconnected cathodes 27 of the PM-OLEDs.

As described above, the periphery region AR′ of the array substrate according to an embodiment of the present invention is provided with PM-OLEDs to enable light emission of the periphery region AR′, and thus a display with narrow bezel design can be realized.

Referring to FIGS. 2 to 6, an embodiment of the present invention provides a method for fabricating the array substrate according to the above embodiments of the present invention, and specifically, the method includes the following steps.

At step one, a buffer layer 11 and an active layer film are sequentially deposited on the substrate 10, and by using a patterning process, a pattern of active layers 12 of the switch transistors is formed in the display region AR and a pattern of the active layers 12 of the transistors of the gate driving circuit is formed in the periphery region AR′. Then, a gate insulation layer 13 is formed on the substrate on which the active layer is formed.

Optionally, the buffer 11 and the gate insulation layer 13 may be both made of silicon oxide (SiOx), silicon nitride (SiNx), hafnium oxide (HfOx), silicon oxynitride (SiOxNy), aluminum oxide (AlOx) or the like, or a multilayer consisting two or three thereof.

Optionally, the active layer may be made of amorphous silicon (a-Si) film or poly silicon (p-Si) film.

At step two, a metal film is deposited on the substrate after subjected to step one, and by using a patterning process, a pattern of gate electrodes 14 of the switch transistors is formed in the display region AR, a pattern of the gate electrodes 14 of the transistors in the gate driving circuit is formed in the periphery region AR′, and a pattern of gate metal lines extending from the display region AR to the periphery region AR′ is formed.

Optionally, the gate metal film may be a single layer or a multilayer laminate made of one or more of Molybdenum (Mo), molybdenum niobium alloy (MoNb), aluminum (Al), aluminum neodymium alloy (LaNd), titanium (Ti) and copper (Cu), and preferably may be a single layer film or a multilayer complex film made of Mo, Al or an alloy containing Mo, Al.

At step three, an interlevel insulation layer 15 is deposited on the substrate subjected to step two, and a contact via is formed for connecting the active layer to source and drain electrodes, the contacting via penetrating the interlevel insulation layer 15 and the gate insulation layer 13.

The interlevel insulation layer 15 may be made of silicon oxide (SiOx), silicon nitride (SiNx), hafnium oxide (HfOx), silicon oxynitride (SiOxNy), aluminum oxide (AlOx) or the like, or a multilayer consisting two or three thereof.

At step four, a source and drain metal film is deposited on the substrate subjected to step three, and by using a patterning process, a pattern of source electrodes 16A and drain electrodes 16B of the switch transistors is formed in the display region AR, a pattern of source electrodes 16A and drain electrodes 16B of the transistors in the gate driving circuit is formed in the periphery region AR′, and a pattern of data lines extending from the display region AR to the periphery region AR′ is formed.

The source and drain metal film may be a single layer or a multilayer laminate made of one or more of Molybdenum (Mo), molybdenum niobium alloy (MoNb), aluminum (Al), aluminum neodymium alloy (LaNd), titanium (Ti) and copper (Cu), and preferably may be a single layer film or a multilayer complex film made of Mo, Al or an alloy containing Mo, Al.

At step five, a planarization layer 17 is deposited on the substrate subjected to step four, and a contact via for connecting a pixel electrode (anode) 18 and the drain electrode 16B is formed in the planarization layer 17.

The planarization layer 17 may be made of silicon oxide (SiOx), silicon nitride (SiNx), hafnium oxide (HfOx), silicon oxynitride (SiOxNy), aluminum oxide (AlOx) or the like, or a multilayer consisting two or three thereof.

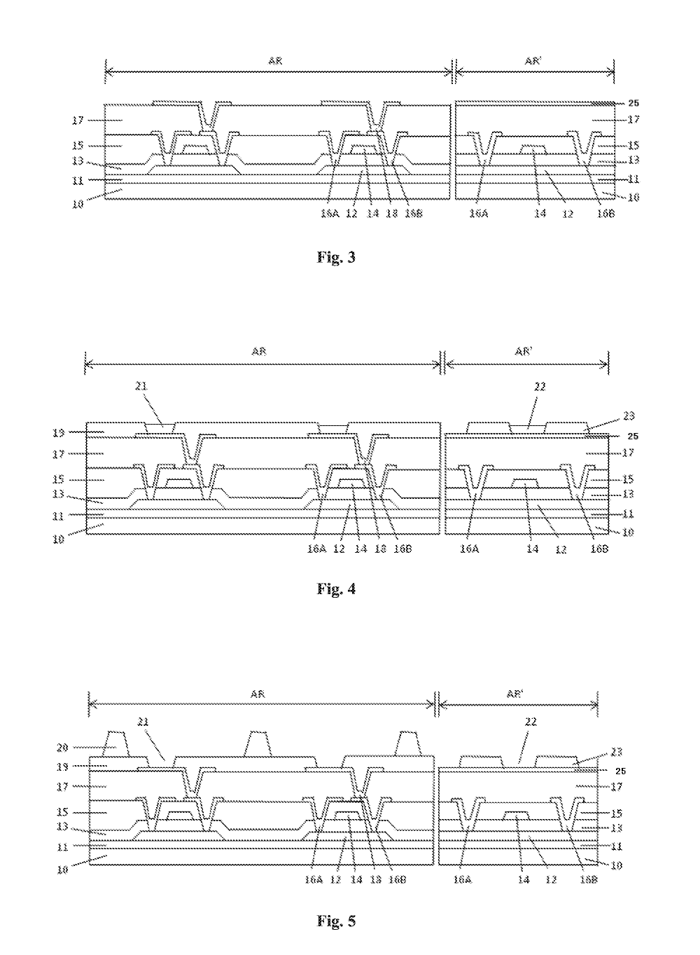

At step six, a first conductive metal layer is deposited on the substrate subjected to step four, and by using a patterning process, a pattern of the anode 18 of the AM-OLED of each pixel is formed in the display region AR (and the anodes 18 are arranged separately), and a pattern of the anode 25 of the PM-OLED of each pixel is formed in the periphery region AR′ (and the anodes 25 disposed in a same row are formed integrally), as illustrated in FIG. 3.

The first conductive metal layer may be made of any one of an ITO (indium tin oxide)/Ag (silver)/ITO (indium tin oxide) structure or an Ag (silver)/ITO (indium tin oxide) structure; alternatively, the ITO in the above structures may be replaced with any one of IZO (indium zinc oxide), IGZO (indium gallium zinc oxide) or InGaSnO (indium gallium tin oxide).

At step seven, a pattern of the pixel defining layer is formed on the substrate subjected to step six by a patterning process, the pixel defining layer including a pixel defining layer 19 of the AM-OLEDs and a pixel defining layer 23 of the PM-OLEDs. Then, a pattern of an AM-OLED light emitting layer 21 and a PM-OLED light emitting layer 22 is formed by one evaporation process, as illustrated in FIG. 4.

The pixel defining layer may be made of silicon oxide (SiOx), silicon nitride (SiNx), hafnium oxide (HfOx), silicon oxynitride (SiOxNy), aluminum oxide (AlOx) or the like, or a multilayer consisting two or three thereof.

The light emitting layer may be made of an undoped fluorescent organic material, or a doped fluorescent organic material consisting of a fluorescence dopant and a matrix.

At step eight, on the substrate subjected to step seven, a plurality of first spacers 20 are formed, by a patterning process, on the pixel defining layer 19 of the AM-OLEDs in the display region AR, wherein the first spacers 20 may have a shape of trapezoid, as illustrated in FIG. 5.

The first spacers 20 may be made of a resin material such as polyimide resin, acrylic resin, phenolic resin.

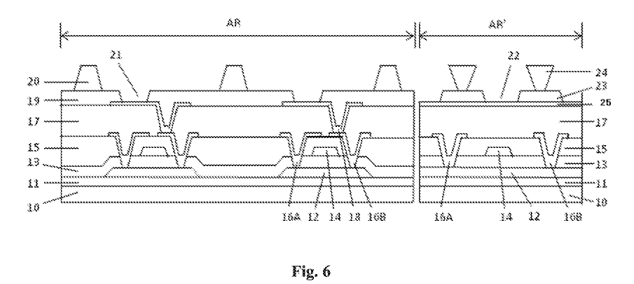

At step nine, on the substrate subjected to step eight, a plurality of second spacers 24 are formed, by a patterning process, on the pixel defining layer 23 of the PM-OLEDs in the periphery region AR′, wherein the second spacers 24 may have a shape of inverted trapezoid, and a negative photoresist is adopted in forming the second spacers, as illustrated in FIG. 6.

The second spacers 24 may be made of a resin material such as polyimide resin, acrylic resin, phenolic resin.

At step ten, a pattern of the cathodes 26 of the AM-OLEDs and a pattern of the cathodes 27 of the PM-OLEDs are formed, by one evaporation process, on the substrate subjected to step nine, wherein the cathodes 26 of the AM-OLEDs are formed integrally and the cathodes 27 of the PM-OLEDs in a same column are formed integrally, as illustrated in FIG. 2.

As a connection layer of an OLED for introducing a negative voltage, the cathode layer has good electrical conductivity and low work function. The cathode layer is generally made of a metal material with low work function, such as lithium, magnesium, calcium, strontium, aluminum, indium or the like, or an alloy of the above metals with copper, gold and silver; alternatively, the cathode layer is made of a thin buffer insulation layer, such as lithium fluoride (LiF), cesium carbonate (CsCO₃) or the like, and the above metals or alloy.

So far, the fabrication of the array substrate has been completed.

Embodiments of the present invention provide a display apparatus including the array substrate according to embodiments of the present invention. The display apparatus may be any product or component with display function, such as an OLED panel, a mobile phone, a tablet computer, a television, a monitor, a notebook computer, a digital album, a navigator or the like.

It can be understood that the foregoing implementations are merely exemplary embodiments used for describing the principle of the present invention, but the present invention is not limited thereto. Those of ordinary skill in the art may make various variations and improvements without departing from the spirit and essence of the present invention, and these variations and improvements shall also fall into the protection scope of the present invention.

1. An array substrate, comprising:
a display region in which a plurality of active-matrix organic light-emitting diodes (AM-OLEDs) are provided; and
a periphery region in which a plurality of passive-matrix organic light-emitting diodes (PM-OLEDs) are provided, the periphery region being on a periphery of the display region,
wherein both of the plurality of AM-OLEDs and the plurality of PM-OLEDs are electrically connected to a power supply driving unit.

2. The array substrate according to claim 1, wherein
top electrodes of the AM-OLEDs and top electrodes the PM-OLEDs are disposed in a same layer and made of a same material;
bottom electrodes of the AM-OLEDs and bottom electrodes the PM-OLEDs are disposed in a same layer and made of a same material; and
a light emitting layer of the AM-OLEDs and a light emitting layer the PM-OLEDs are disposed in a same layer and made of a same material.

3. The array substrate according to claim 1, wherein the plurality of PM-OLEDs are arranged in a matrix, the bottom electrodes of the PM-OLEDs in a same row are connected to each other to form an integral structure, and the top electrodes of the PM-OLEDs in a same column are connected to each other to form an integral structure.

4. The array substrate according to claim 1, further comprising:
a gate driving circuit disposed, in the periphery region, under a layer at which the PM-OLEDs are positioned, the gate driving circuit being configured to drive the plurality of AM-OLEDs.

5. The array substrate according to claim 1, further comprising:
a plurality of switch transistors disposed, in the display region, under a layer at which the AM-OLEDs are positioned,
wherein a drain electrode of each of the plurality of switch transistors is connected to a bottom electrode of a corresponding one of the plurality of AM-OLEDs.

6. The array substrate according to claim 1, further comprising:
a plurality of first spacers disposed on a pixel defining layer of the AM-OLEDs in the display region; and
a plurality of second spacers disposed on a pixel defining layer of the PM-OLEDs in the periphery region.

7. The array substrate according to claim 6, wherein each of the first spacers has a shape of trapezoid and each of the second spacers has a shape of inverted trapezoid.

8. The array substrate according to claim 1, wherein the top electrodes of the AM-OLEDs are formed integrally.

9. The array substrate according to claim 1, further comprising a non-display region located on an outermost periphery of the array substrate, the non-display region corresponding to a bezel of the array substrate.

10. A method for fabricating an array substrate, the array substrate comprising a display region and a periphery region on a periphery of the display region, the method comprising:
forming a plurality of AM-OLEDs on a substrate in the display region; and
forming a plurality of PM-OLEDs on the substrate in the periphery region,
wherein both of the plurality of AM-OLEDs and the plurality PM-OLEDs are electrically connected to a power supply driving unit.

11. The method according to claim 10, wherein
top electrodes of the AM-OLEDs and top electrodes of the PM-OLEDs are formed by one patterning process;
bottom electrodes of the AM-OLEDs and bottom electrodes of the PM-OLEDs are formed by one patterning process; and
a light emitting layer of the AM-OLEDs and a light emitting layer of the PM-OLEDs are formed by one patterning process.

12. The method according to claim 11, before forming the top electrodes of the AM-OLEDs and the top electrodes of the PM-OLEDs by one patterning process, further comprising:
forming a plurality of first spacers on a pixel defining layer of the AM-OLEDs in the display region; and
forming a plurality of second spacers on a pixel defining layer of the PM-OLEDs in the periphery region.

13. The method according to claim 12, wherein each of the first spacers is formed to have a shape of trapezoid, and each of the second spacers is formed to have a shape of inverted trapezoid.

14. The method according to claim 10, wherein the plurality of PM-OLEDs are formed to be arranged in a matrix, bottom electrodes of the PM-OLEDs in a same row are formed integrally, and top electrodes of the PM-OLEDs in a same column are formed integrally.

15. The method according to claim 10, before forming the plurality of PM-OLEDs in the periphery region, further comprising:
forming a gate driving circuit on the substrate in the periphery region.

16. The method according to claim 15, before forming the plurality of AM-OLEDs in the display region, further comprising:
forming switch transistors on the substrate in the display region, wherein the switch transistors on the substrate in the display region and the gate driving circuit on the substrate in the periphery region are formed by a same patterning process.

17. The method according to claim 10, before forming the plurality of AM-OLEDs in the display region, further comprising:
forming a plurality of switch transistors on the substrate in the display region; and
forming a planarization layer on the plurality of switch transistors, and forming, on a drain electrode of each of the plurality of switch transistors, a via penetrating the planarization layer,
wherein the drain electrode of each of the plurality of switch transistors is connected to a bottom electrode of a corresponding one of the AM-OLEDs through the via.

18. A display apparatus, comprising the array substrate according to claim 1.
